(19) United States
(12) Patent Application Publication
(10) Pub. No.: US 2018/0308601 A1
(43) Pub. Date: Oct. 25, 2018

(54) SYSTEMS AND METHODS FOR ENERGY STORAGE

(71) Applicant: Nimbus Engineering Inc., San Francisco, CA (US)

(72) Inventor: Alex DIGGINS, San Francisco, CA (US)

(21) Appl. No.: 15/493,823

(22) Filed: Apr. 21, 2017

(51) Int. Cl. G21H 1/12; H01L 31/055; H01L 31/0352; H01L 31/16; H01L 31/167

(52) U.S. Cl. CPC G21H 1/12; H01L 31/055; H02N 11/008; H01L 31/165; H01L 31/167; H01L 31/035281

(57) ABSTRACT

Provided herein are systems and methods for storing energy. A photon battery assembly may comprise a light source, phosphorescent material, and a photovoltaic cell. The phosphorescent material can absorb optical energy at a first wavelength from the light source and, after a time delay, emit optical energy at a second wavelength after a time delay. The photovoltaic cell may absorb the optical energy at the second wavelength and generate electrical power. In some instances, radioactive material can emit high energy particles, and the phosphorescent material can absorb kinetic energy from the high energy particles.

### BACKGROUND

Especially in an age where so many activities and functions depend on a continuous supply of power, lapses or interruptions in the provision of power may lead to highly undesirable results. These recent years have seen a fast-growing market for readily accessible power, such as in batteries, supercapacitors, fuel cells, and other energy storage devices. However, such energy storage devices are often limited in many aspects. For example, they may be volatile or unstable under certain operating conditions (e.g., temperature, pressure) and become ineffective or pose a safety hazard. In some cases, an energy storage device may itself be consumed during one or more cycles of converting or storing energy and thus have limited lifetime. In some cases, a rate of charging may be too slow to effectively support or satisfy a rate of consumption of power.

### SUMMARY

Recognized herein is a need for reliable systems and methods for energy storage. The systems and methods for energy storage disclosed herein may provide superior charging rates to those of conventional chemical batteries, for example, on the order of 100 times faster or more. The systems and methods disclosed herein may provide superior lifetimes to those of conventional chemical batteries, for example, on the order of 10 times more recharge cycles or more. The systems and methods disclosed herein may be portable. The systems and methods disclosed herein may be stable and effective in relatively cold operating temperature conditions.

The systems and methods disclosed herein may use phosphorescent material to store energy over a finite duration of time. For example, the phosphorescent material may store and/or convert energy with substantial time delay. The systems and methods disclosed herein may use light sources to provide an initial source of energy in the form of optical energy. The light sources can be artificial light sources, such as light emitting diodes (LEDs). The systems and methods disclosed herein may use photovoltaic cells to generate electrical power from optical energy. In some embodiments, the systems and methods disclosed herein may use radioactive material to excite (or otherwise stimulate) the phosphorescent material.

In an aspect, provided is a system for storing energy. The system can comprise: a light source configured to emit optical energy at a first wavelength from a surface of the light source; a phosphorescent material adjacent to the surface of the light source, wherein the phosphorescent material is configured to (i) absorb the optical energy at the first wavelength, and (ii) at a rate slower than a rate of absorption, emit optical energy at a second wavelength, wherein the second wavelength is greater than the first wavelength; and a photovoltaic cell adjacent to the phosphorescent material, wherein the photovoltaic cell is configured to (i) absorb optical energy at the second wavelength through a surface of the photovoltaic cell, and (ii) generate electrical power from optical energy.

In some embodiments, the light source is a light-emitting diode (LED).

In some embodiments, the photovoltaic cell is electrically coupled to an electrical load. In some embodiments, at least part of the electrical power generated by the photovoltaic cell powers the electrical load.

In some embodiments, the photovoltaic cell is electrically coupled to the light source. In some embodiments, at least part of the electrical power generated by the photovoltaic cell powers the light source.

In some embodiments, a rechargeable battery is electrically coupled to the light source and the photovoltaic cell. In some embodiments, at least part of the electrical power generated by the photovoltaic cell charges the rechargeable battery, and wherein at least part of electrical power discharged by the rechargeable battery powers the light source.

In some embodiments, the first wavelength is an ultraviolet wavelength.

In some embodiments, the second wavelength is a visible wavelength.

In some embodiments, the phosphorescent material comprises strontium aluminate and europium.

In some embodiments, the system further comprises a radioactive material that emits high energy particles, wherein the high energy particles are capable of travelling through the phosphorescent material, wherein the phosphorescent material is configured to (i) absorb kinetic energy from the high energy particles, and (ii) at a rate slower than the rate of absorption of kinetic energy, emit optical energy at the second wavelength.

In some embodiments, the phosphorescent material is adjacent to the radioactive material. In some embodiments, the phosphorescent material comprises the radioactive material. In some embodiments, the radioactive material is strontium-90.

In some embodiments, the photovoltaic cell comprises a plurality of depressions between protrusions and wherein the surface of the photovoltaic cell is a surface of a protrusion defining a depression.

In another aspect, provided is a method for storing energy. The method can comprise: emitting optical energy at a first wavelength from a surface of a light source; absorbing, by a phosphorescent material adjacent to the surface of the light source, the optical energy at the first wavelength; at a rate slower than a rate of absorption, emitting, by the phosphorescent material, optical energy at a second wavelength, wherein the second wavelength is greater than the first wavelength; absorbing the optical energy at the second wavelength through a surface of a photovoltaic cell, wherein the surface of the photovoltaic cell is adjacent to the phosphor; and generating electrical power from the optical energy at the second wavelength.

In some embodiments, the light source is a light-emitting diode (LED).

In some embodiments, the method can further comprise powering an electrical load electrically coupled to the photovoltaic cell using the electrical power. For example, the electrical load can be a mobile device. In another example, the electrical load can be an electric car.

In some embodiments, the method can further comprise powering the light source using at least part of the electrical power, wherein the light source is electrically coupled to the photovoltaic cell.

In some embodiments, the method can further comprise charging a rechargeable battery using at least part of the electrical power, wherein the rechargeable battery is electrically coupled to the photovoltaic cell. In some embodiments, the method can further comprise powering the light source using at least part of electrical power discharged by the rechargeable battery, wherein the rechargeable battery is electrically coupled to the light source.

In some embodiments, the first wavelength is an ultraviolet wavelength.

In some embodiments, the second wavelength is a visible wavelength.

In some embodiments, the phosphorescent material comprises strontium aluminate and europium.

In some embodiments, the photovoltaic cell comprises a plurality of depressions between protrusions and wherein the surface of the photovoltaic cell is a surface of a protrusion defining a depression.

In another aspect, provided is a method for storing energy. The method can comprise: emitting high energy particles from a radioactive material, wherein the high energy particles travel through a phosphorescent material; absorbing, by the phosphorescent material, kinetic energy from the high energy particles; at a rate slower than a rate of absorption of the kinetic energy, emitting, by the phosphorescent material, optical energy; absorbing the optical energy through a surface of a photovoltaic cell, wherein the surface of the photovoltaic cell is adjacent to the phosphor; and generating electrical power from the optical energy.

In some embodiments, the radioactive material is adjacent to the phosphorescent material.

In some embodiments, the phosphorescent material comprises the radioactive material.

In some embodiments, the method can further comprise powering an electrical load electrically coupled to the photovoltaic cell using the electrical power.

In some embodiments, the optical energy is at a visible wavelength.

In some embodiments, the photovoltaic cell comprises a plurality of depressions between protrusions and wherein the surface of the photovoltaic cell is a surface of a protrusion defining a depression.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “Figure” and “FIG.” herein) of which:

FIG. 1 shows an exemplary photon battery assembly.

FIG. 2 shows a photon battery in communication with an electrical load.

FIG. 3 shows an exemplary photon battery assembly in application.

FIG. 4 shows an exemplary photon battery assembly that is self-sustaining in part.

FIG. 5 shows an exemplary photon battery assembly in communication with a rechargeable battery.

FIG. 6 shows a stack of a plurality of photon battery assemblies.

FIG. 7 shows a cross-sectional side view of an exemplary trench configuration of a photon battery assembly.

FIG. 8 shows a cross-sectional top view of an exemplary trench configuration of a photon battery assembly.

FIG. 9 shows a photon battery assembly comprising radioactive material.

FIG. 10 shows a photon battery assembly comprising radioactive material in the phosphorescent material.

FIG. 11 illustrates a method of storing energy in a photon battery.

FIG. 12 illustrates a method of storing energy in a photon battery using radioactive material.

FIG. 13 shows a computer control system.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

Provided herein are systems and methods for energy storage. The systems and methods disclosed herein may use phosphorescent material to store energy over a significant duration of time, such as by making use of the time-delayed re-emission properties of phosphorescent material. For example, the phosphorescent material may store and/or convert energy with substantial time delay. A light source can provide an initial source of energy to the phosphorescent material in the form of optical energy. For example, the phosphorescent material may absorb optical energy from the light source at a first wavelength, and after a time delay, emit optical energy at a second wavelength. The light source can be an artificial light source, such as a light emitting diode (LED). A photovoltaic cell can generate electrical power from optical energy, such as from optical energy at the second wavelength that is emitted by the phosphorescent material.

Alternatively or in addition, the phosphorescent material may absorb kinetic energy, and after a time delay, emit optical energy converted from the kinetic energy to be absorbed by the photovoltaic cell. For example, radioactive material can excite the phosphorescent material with high energy particles (having high kinetic energy). In some cases, the phosphorescent material may itself comprise radioactive material.

The systems and methods for energy storage disclosed herein may provide superior charging rates to those of conventional chemical batteries, for example, on the order of 100 times faster or more. The systems and methods disclosed herein may provide superior lifetimes to those of conventional chemical batteries, for example, on the order of 10 times more recharge cycles or more. The systems and methods disclosed herein may be portable. The systems and methods disclosed herein may be stable and effective in relatively cold operating temperature conditions.

Reference will now be made to the figures. It will be appreciated that the figures and features therein are not necessarily drawn to scale.

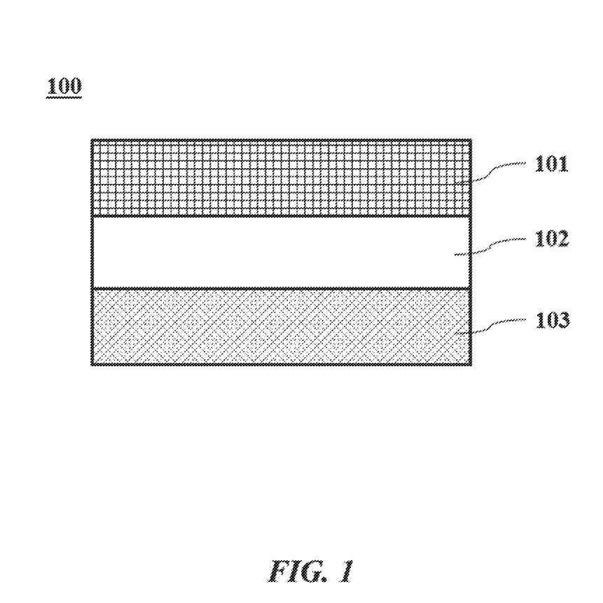

FIG. 1 shows an exemplary photon battery assembly. A photon battery assembly 100 can comprise a light source 101, a phosphorescent material 102, and a photovoltaic cell 103. The phosphorescent material may be adjacent to both the light source and the photovoltaic cell. For example, the phosphorescent material can be sandwiched by the light source and the photovoltaic cell. The phosphorescent material can be between the light source and the photovoltaic cell. While FIG. 1 shows the light source, phosphorescent material, and photovoltaic cell as a vertical stack, the configuration is not limited as such. For example, the light source, phosphorescent material, and photovoltaic cell can be horizontally stacked or concentrically stacked. The light source and the photovoltaic cell may or may not be adjacent to each other. In some instances, the phosphorescent material can be adjacent to a light-emitting surface of the light source. In some instances, the phosphorescent material can be adjacent to a light-absorbing surface of the photovoltaic cell.

While adjacent, the phosphorescent material 102 may or may not be contacting the light source 101. If the phosphorescent material and the light source are in contact, the phosphorescent material can interface a light-emitting surface of the light source. The phosphorescent material and the light source can be coupled or fastened together at the interface, such as via a fastening mechanism. In some instances, a support carrying the light source and/or a support carrying the phosphorescent material may be coupled or fastened together at the interface. Examples of fastening mechanisms may include, but are not limited to, form-fitting pairs, hooks and loops, latches, staples, clips, clamps, prongs, rings, brads, rubber bands, rivets, grommets, pins, ties, snaps, velcro, adhesives, tapes, a combination thereof, or any other types of fastening mechanisms. In some instances, the phosphorescent material may have adhesive and/or cohesive properties and adhere to the light source without an independent fastening mechanism. For example, the phosphorescent material may be painted or coated on the light-emitting surface of the light source. In some instances, the phosphorescent material may be coated onto primary, secondary, and/or tertiary optics of the light source. In some instances, the phosphorescent material may be coated onto other optical elements of the light source. The phosphorescent material and the light source can be permanently or detachably fastened together. For example, the phosphorescent material and the light source can be disassembled from and reassembled into the photon battery assembly 100 without damage (or with minimal damage) to the phosphorescent material and/or the light source. Alternatively, while in contact, the phosphorescent material and the light source may not be fastened together.

If the phosphorescent material 102 and the light source 101 are not in contact, the phosphorescent material can otherwise be in optical communication with a light-emitting surface of the light source. For example, the phosphorescent material can be positioned in an optical path of light emitted by the light-emitting surface of the light source. In some instances, there can be an air gap between the phosphorescent material and the light source. In some instances, there can be another intermediary layer between the phosphorescent material and the light source. The intermediary layer can be air or other fluid. The intermediary layer can be a light guide or another layer of optical elements (e.g., lens, reflector, diffusor, beam splitter, etc.). In some instances, there can be a plurality of intermediary layers between the phosphorescent material and the light source.

While adjacent, the phosphorescent material 102 may or may not be contacting the photovoltaic cell 103. If the phosphorescent material and the photovoltaic cell are in contact, the phosphorescent material can interface a light-absorbing surface of the photovoltaic cell. The phosphorescent material and the photovoltaic cell can be coupled or fastened together at the interface, such as via a fastening mechanism. In some instances, a support carrying the photovoltaic cell and/or a support carrying the phosphorescent material may be coupled or fastened together at the interface. In some instances, the phosphorescent material may have adhesive properties and adhere to the photovoltaic cell without an independent fastening mechanism. For example, the phosphorescent material may be painted or coated on the light-absorbing surface of the photovoltaic cell. In some instances, the phosphorescent material may be coated onto primary, secondary, and/or tertiary optics of the photovoltaic cell. In some instances, the phosphorescent material may be coated onto other optical elements of the photovoltaic cell. The phosphorescent material and the photovoltaic cell can be permanently or detachably fastened together. For example, the phosphorescent material and the photovoltaic cell can be disassembled from and reassembled into the photon battery assembly 100 without damage (or with minimal damage) to the phosphorescent material and/or the photovoltaic cell. Alternatively, while in contact, the phosphorescent material and the photovoltaic cell may not be fastened together.

If the phosphorescent material 102 and the photovoltaic cell 103 are not in contact, the phosphorescent material can otherwise be in optical communication with a light-absorbing surface of the photovoltaic cell. For example, the light-absorbing surface of the photovoltaic cell can be positioned in an optical path of light emitted by the phosphorescent material. In some instances, there can be an air gap between the phosphorescent material and the photovoltaic cell. In some instances, there can be another intermediary layer between the phosphorescent material and the photovoltaic cell. The intermediary layer can be air or other fluid. The intermediary layer can be a light guide, light concentrator, or another layer of optical elements (e.g., lens, reflector, diffusor, beam splitter, etc.). In some instances, there can be a plurality of intermediary layers between the phosphorescent material and the photovoltaic cell.

In some instances, the photon battery assembly 100 can be assembled or disassembled, such as into the light source 101, phosphorescent material 102, or the photovoltaic cell 103 independently, or into sub-combinations thereof. In some instances, the photon battery assembly can be assembled or disassembled without damage to the different parts or with minimal damage to the different parts.

In some instances, the photon battery assembly 100 can be housed in a shell, outer casing, or other housing. The photon battery assembly 100, and/or shell thereof can be portable. For example, the photon battery assembly can have a maximum dimension of at most about 1 meter (m), 90 centimeters (cm), 80 cm, 70 cm, 60 cm, 50 cm, 45 cm, 40 cm, 35 cm, 30 cm, 25 cm, 20 cm, 15 cm, 10 cm, 9 cm, 8 cm, 7 cm, 6 cm, 5 cm, or smaller. A maximum dimension of the photon battery assembly may be a dimension of the photon battery assembly (e.g., length, width, height, depth, diameter, etc.) that is greater than the other dimensions of the photon battery assembly. Alternatively, the photon battery assembly may have greater maximum dimensions. For example, a photon battery assembly having a higher energy storage capacity can have larger dimensions and may not be portable.

The light source 101 can be an artificial light source, such as a light emitting diode (LED) or other light emitting device. For example, the light source can be a laser or a lamp. The light source can be a plurality of light emitting devices (e.g., a plurality of LEDs). In some instances, the light source can be arranged as one LED. In some instances, the light source can be arranged as rows or columns of multiple LEDs. The light source can be arranged as arrays or grids of multiple columns, rows, or other axes of LEDs. The light source can be a combination of different light emitting devices. A light emitting surface of the light source can be planar or non-planar. A light emitting surface of the light source can be substantially flat, substantially curved, or form another shape. The light source can be supported by rigid and/or flexible supports. For example, the supports can direct the light emitted by the light source to be directional or non-directional. In some instances, the light source can comprise primary and/or secondary optical elements. In some instances, the light source can comprise tertiary optical elements. In some instances, the light source can comprise other optical elements at other levels or layers (e.g., lens, reflector, diffusor, beam splitter, etc.). The light source can be configured to convert electrical energy to optical energy. For example, the light source can be powered by an electrical power source, which may be external or internal to the photon battery assembly 100. The light source can be configured to emit optical energy (e.g., as photons), such as in the form of electromagnetic waves. In some instances, the light source can be configured to emit optical energy at a wavelength or a range of wavelengths that is capable of being absorbed by the phosphorescent material 102. For example, the light source can emit light at wavelengths in the ultraviolet range (e.g., 10 nanometers (nm) to 400 nm). In some instances, the light source can emit light at other wavelengths or ranges of wavelengths in the electromagnetic spectrum (e.g., infrared, visible, ultraviolet, x-rays, etc.).

In some instances, the light source 101 can be a natural light source (e.g., sun light), in which case the phosphorescent material 102 in the photon battery assembly 100 may be exposed to the natural light source to absorb such natural light.

The phosphorescent material 102 can absorb optical energy at a first wavelength (or first wavelength range) and emit optical energy at a second wavelength (or second wavelength range) after a substantial time delay. The second wavelength can be a different wavelength than the first wavelength. The optical energy at the first wavelength that is absorbed by the phosphorescent material can be at a higher energy level than the optical energy at the second wavelength that is emitted by the phosphorescent material. The second wavelength can be greater than the first wavelength. In an example, the phosphorescent material can absorb energy at ultraviolet range wavelengths (e.g., 10 nm to 400 nm) and emit energy at visible range wavelengths (e.g., 400 nm to 700 nm). For example, the phosphorescent material can absorb blue photons and, after a time delay, emit green photons. The phosphorescent material can absorb optical energy (e.g., photons) at other wavelengths (or ranges of wavelengths) and emit optical energy at other wavelengths (or ranges of wavelengths), such as in the electromagnetic spectrum (e.g., infrared, visible, ultraviolet, x-rays, etc.) wherein the energy emitted is at a lower energy level than the energy absorbed. A rate of emission of optical energy by the phosphorescent material can be slower than a rate of absorption of optical energy by the phosphorescent material. An advantage of this difference in rate is the ability of the phosphorescent material to release energy at a slower rate than absorbing such energy, thus storing the energy during such time delay.

The phosphorescent material can be crystalline, solid, liquid, ceramic, in powder form, liquid form, or in any other shape, state, or form. The phosphorescent material can be long-lasting phosphors. In an example, the phosphorescent material can comprise strontium aluminate doped with europium (e.g., SrAl₂O₄:Eu). Some other examples of phosphorescent material can include, but are not limited to, zinc gallogermanates (e.g., Zn₃Ga₂Ge₂O₁₀:0.5% Cr³⁺), zinc sulfide doped with copper and/or cobalt (e.g., ZnS:Cu, Co), strontium aluminate doped with other dopants, such as europium, dysprosium, and/or boron (e.g., SrAl₂O₄:Eu²⁺, Dy³⁺,B³⁺), calcium aluminate doped with europium, dysprosium, and/or neodymium (e.g., CaAl₂O₄:Eu²⁺, Dy³⁺, Nd³⁺), yttrium oxide sulfie doped with europium, magnesium, and/or titanium, (e.g., Y₂O₂S:Eu³⁺, Mg²⁺, Ti⁴⁺), and zinc gallogermanates (e.g., Zn₃Ga₂Ge₂O₁₀:0.5% Cr³⁺). In some instances, the afterglow (e.g., emitted optical energy) emitted by the phosphorescent material can last at least about 1 hour (hr), 2 hr, 3 hr, 4 hr, 5 hr, 6 hr, 7 hr, 8 hr, 9 hr, 10 hr, 11 hr, 12 hr, 1 day, 2 days, 3 days, 4 days, 1 week, 2 weeks, 3 weeks, or longer. In some instances, the phosphorescent material can store and/or discharge energy for at least about 1 hr, 2 hr, 3 hr, 4 hr, 5 hr, 6 hr, 7 hr, 8 hr, 9 hr, 10 hr, 11 hr, 12 hr, 1 day, 2 days, 3 days, 4 days, 1 week, 2 weeks, 3 weeks, or longer. Alternatively, the afterglow emitted by the phosphorescent material (or energy stored by the phosphorescent material) can last for shorter durations.

The assembly 100 can comprise one or a plurality of photovoltaic cells (e.g., photovoltaic cell 103) that are electrically connected in series and/or in parallel. The photovoltaic cell 103 can be a panel, cell, module, and/or other unit. For example, a panel can comprise one or more cells all oriented in a plane of the panel and electrically connected in various configurations. For example, a module can comprise one or more cells electrically connected in various configurations. The photovoltaic cell 103, or solar cell, can be configured to absorb optical energy and generate electrical power from the absorbed optical energy. In some instances, the photovoltaic cell can be configured to absorb optical energy at a wavelength or a range of wavelengths that is capable of being emitted by the phosphorescent material 102. The photovoltaic cell can have a single band gap that is tailored to the wavelength (or range of wavelengths) of the optical energy that is emitted by the phosphorescent material. Beneficially, this may increase the efficiency of the energy storage system of the photon battery assembly 100. For example, for strontium aluminate doped with europium as the phosphorescent material, the photovoltaic cell can have a band gap that is tailored to the green light wavelength (e.g., 500-520 nm). Similarly, the light source 101 can be tailored to emit ultraviolet range wavelengths (e.g., 20 nm to 400 nm). Alternatively, the photovoltaic cell can be configured to absorb optical energy at other wavelengths (or ranges of wavelengths) in the electromagnetic spectrum (e.g., infrared, visible, ultraviolet, x-rays, etc.).

In some embodiments, organic light emitting diodes (OLEDs) can replace the phosphorescent material 102 in the photon battery assembly 100. In some embodiments, OLEDs can replace both the light source 101 and the phosphorescent material. OLEDs can be capable of electro-phosphorescence, where quasi particles in the lattice of the diodes store potential energy from an electric power source and release such energy over time in the form of optical energy at visible wavelengths (e.g., 400 nm to 700 nm). For example, OLEDs can be powered by an electrical power source, which may be external or internal to the photon battery assembly 100. A light-emitting surface of the OLEDs can interface with a light-absorbing surface of the photovoltaic cell 103 to complete the photon battery assembly. For example, with OLEDs, the photovoltaic cell can have a band gap that is tailored to the visible wavelength range (e.g., 400-700 nm).

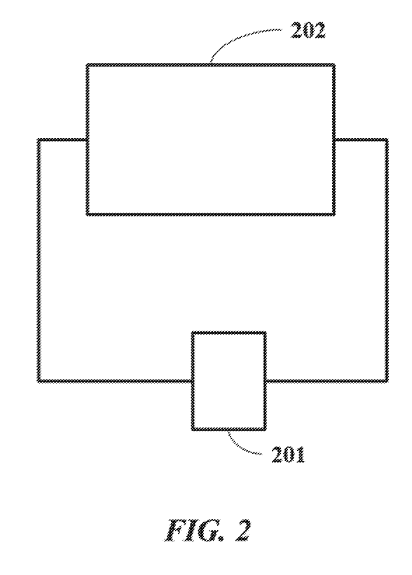

FIG. 2 shows a photon battery in communication with an electrical load. The photon battery 201 can power an electrical load 202. The photon battery and the electrical load can be in electric communication, such as via an electric circuit. While FIG. 2 shows a circuit, the circuit configuration is not limited to the one shown in FIG. 2. The electrical load can be an electrical power consuming device. The electrical load can be an electronic device, such as a personal computer (e.g., portable PC), slate or tablet PC (e.g., Apple® iPad, Samsung® Galaxy Tab), telephone, Smart phone (e.g., Apple® iPhone, Android-enabled device, Blackberry®), or personal digital assistant. The electronic device can be mobile or non-mobile. The electrical load can be a vehicle, such as an automobile, electric car, train, boat, or airplane. The electrical load can be a power grid. In some cases, the electrical load can be another battery or other energy storage system which is charged by the photon battery. In some instances, the photon battery can be integrated in the electrical load. In some instances, the photon battery can be permanently or detachably coupled to the electrical load. For example, the photon battery can be removable from the electrical load.

In some cases, a photon battery 201 can power a plurality of electrical loads in series or in parallel. In some cases, a photon battery can power a plurality of electrical loads simultaneously. For example, the photon battery can power 2, 3, 4, 5, 6, 7, 8, 9, 10 or more electrical loads simultaneously. In some cases, a plurality of photon batteries, electrically connected in series or in parallel, can power an electrical load. In some cases, a combination of one or more photon batteries and one or more other types of energy storage systems (e.g., lithium ion battery, fuel cell, etc.) can power one or more electrical loads.

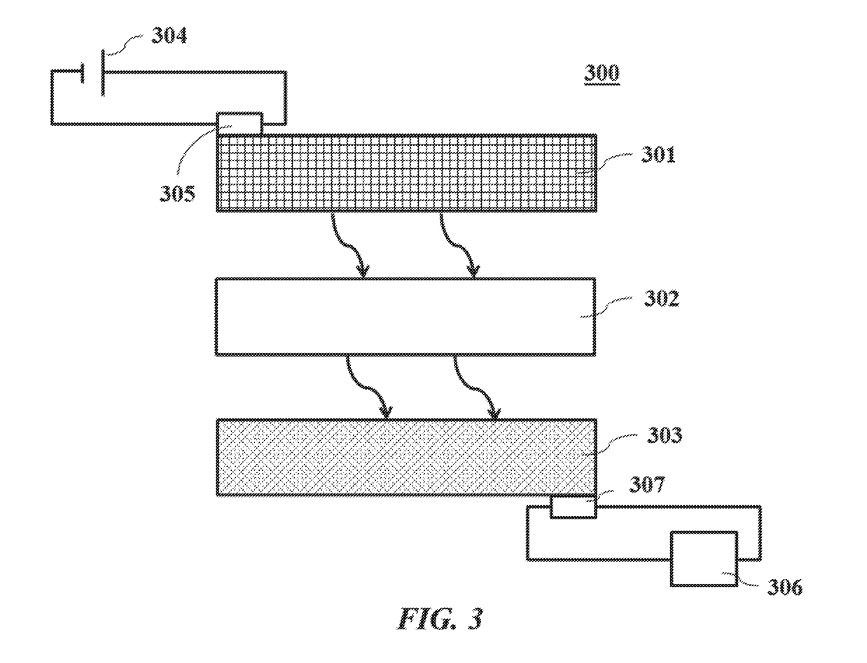

FIG. 3 shows an exemplary photon battery assembly in application. Any and all circuits illustrated in FIG. 3 are not limited to such circuitry configurations. A photon battery assembly 300 can be charged by a power source 304 and discharge power to an electrical load 306. The photon battery assembly can comprise a light source 301, such as a LED or a set of LEDs. The light source can be in electrical communication with the power source 304 through a port 305 of the light source. For example, the power source and the port 305 can be electrically connected via a circuit. The power source 304 may be external or internal to the photon battery assembly 300. The power source can be a power supplying device, such as another energy storage system (e.g., another photon battery, lithium ion battery, supercapacitor, fuel cell, etc.). The power source can be an electrical grid.

The light source 301 can receive electrical energy and emit optical energy at a first wavelength, such as via a light-emitting surface of the light source. The light-emitting surface can be adjacent to a phosphorescent material 302. The light source can be in optical communication with the phosphorescent material. The phosphorescent material can be configured to absorb optical energy at the first wavelength and, after a time delay, emit optical energy at a second wavelength. In some cases, the rate of emission of the optical energy at the second wavelength can be slower than the rate of absorption of the optical energy at the first wavelength. An advantage of this difference in rate is the ability of the phosphorescent material to release energy at a slower rate than absorbing such energy, thus storing the energy during such time delay. In some instances, the phosphorescent material can store and/or discharge energy for at least about 1 hr, 2 hr, 3 hr, 4 hr, 5 hr, 6 hr, 7 hr, 8 hr, 9 hr, 10 hr, 11 hr, 12 hr, 1 day, 2 days, 3 days, 4 days, 1 week, 2 weeks, 3 weeks, or longer.

The photon battery assembly can comprise a photovoltaic cell 303. The photovoltaic cell can be configured to absorb optical energy at the second wavelength, such as via a light-absorbing surface of the photovoltaic cell. The photovoltaic cell can be in optical communication with the phosphorescent material 302. The light-absorbing surface of the photovoltaic cell can be adjacent to the phosphorescent material. The photovoltaic cell can generate electrical power from the optical energy absorbed. The electrical power generated by the photovoltaic cell can be used to power an electrical load 306. The photovoltaic cell can be in electrical communication with the electrical load through a port 307 of the photovoltaic cell. For example, the electrical load and the port 307 can be electrically connected via a circuit.

The energy stored by the photon battery assembly 300 can be charged and/or recharged multiple times. The power generated by the photon battery assembly can be consumed multiple times. The photon battery assembly can be charged and/or recharged by supplying electrical energy (or power) to the light source 301, such as through the port 305. The photon battery assembly 300 can discharge power by directing electrical power generated by the photovoltaic cell to the electrical load 306, such as through the port 307. For example, the photon battery assembly 300 can last (e.g., function for) at least 1, 2, 3, 4, 5, 6, 7, 8, 9, 10, 100, 500, 1000, 10⁴, 10⁵, 10⁶, or more recharge (or consumption) cycles.

The photon battery assembly 300 may provide superior charging rates to those of conventional chemical batteries, for example, on the order of 2, 3, 4, 5, 6, 7, 8, 9, 10, 20, 30, 40, 50, 60, 70, 80, 90, 100 times faster or more. For example, the photon battery assembly can charge at a speed of at least about 800 watts per cubic centimeters (W/cc), 850 W/cc, 900 W/cc, 1000 W/cc, 1050 W/cc, 1100 W/cc, 1150 W/cc, 1200 W/cc, 1250 W/cc, 1300 W/cc, 1350 W/cc, 1400 W/cc, 1450 W/cc, 1500 W/cc or greater. Alternatively, the photon battery assembly can charge at a speed of less than about 800 W/cc. The photon battery assembly may provide superior lifetimes to those of conventional chemical batteries, for example, on the order of 2, 3, 4, 5, 6, 7, 8, 9, 10 times more recharge cycles or more.

The photon battery assembly 300 may be stable and function effectively in relatively cold operating temperature conditions. For example, the photon battery assembly may function stably in operating temperatures as low as about −55° Celsius (° C.) and as high as about 65° C. The photon battery assembly may function stably in operating temperatures lower than about −55° C. and higher than about 65° C. In some instances, the photon battery assembly may function stably under any operating temperatures for which the light source (e.g., LEDs) functions stably. The photon battery assembly may not generate excess operating heat.

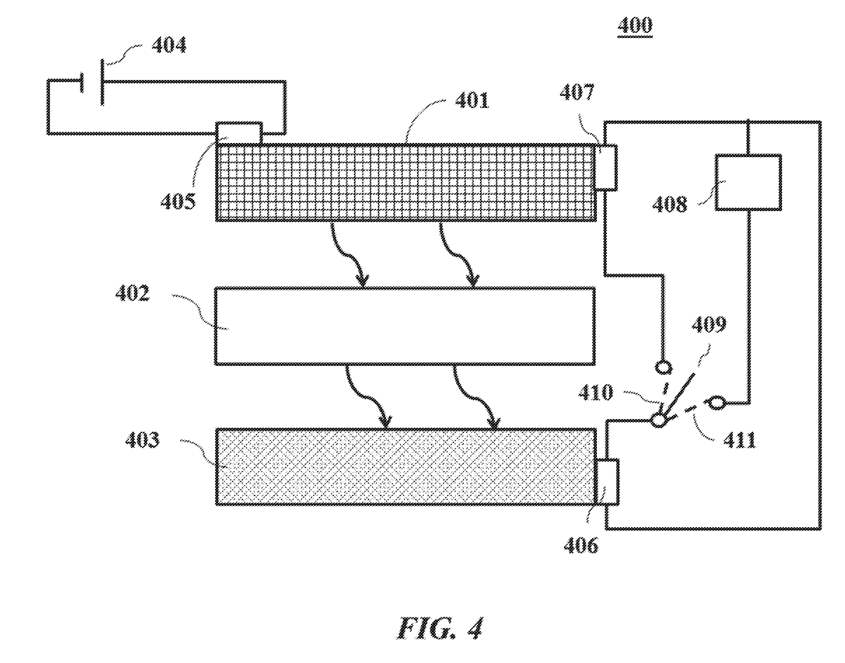

FIG. 4 shows an exemplary photon battery assembly that is self-sustaining in part. Any and all circuits illustrated in FIG. 4 are not limited to such circuitry configurations. A photon battery assembly 400 can be charged by a power source 404 (e.g., electrical grid, different energy storage system such as a battery, etc.) and discharge power to an electrical load 408. However, the electrical load 408 or other electrical loads that may draw power from the photon battery assembly may not necessarily be connected to the photon battery assembly at all times. In some instances, the photon battery assembly may discharge more power than is consumed by the electrical load connected to the photon battery assembly. In such cases, at least some of the power generated by the photovoltaic cell 403 can be wasted or lost from the energy storage system (e.g., photon battery assembly 400). When no electrical load is connected to the photon battery assembly, in some instances, the power generated by the photon battery assembly can be directed back into the photon battery assembly. Alternatively or in addition, when an electrical load is consuming a less amount of power than is being produced by the photon assembly, some of the power can be directed into the photon battery assembly. For example, at least some power generated by the photovoltaic cell can be directed to power the light source 401.

In some instances, the photon battery assembly 400 in FIG. 4 and corresponding components thereof can parallel the photon battery assembly 300 in FIG. 3 and corresponding components thereof.

The photon battery assembly 400 can comprise a light source 401 powered primarily by a power source 404, such as through a first port 405 of the light source, a phosphorescent material 402 adjacent to a light-emitting surface of the light source, and a photovoltaic cell 403, which light-absorbing surface of the photovoltaic cell is adjacent to the phosphorescent material. The photovoltaic cell can discharge power to an electrical load 408 when the electrical load is in electrical communication with the photovoltaic cell. The photovoltaic cell can discharge power to the light source when the electrical load is not in electrical communication with the photovoltaic cell.

For example, a circuitry of the photon battery assembly 400 can comprise a switch 409 that either completes a first electric path 410 or a second electric path 411. In some cases, the switch can complete neither electric path (e.g., as shown in FIG. 4), and when neither electric path is completed, the power generated by the photon battery assembly can be wasted or lost from the energy storage system. The first electric path 410 can be completed when no electrical load (e.g., electrical load 408) is connected to the photon battery assembly 400. In some instances, completing the first electric path 410 can be the default state of the switch 409. When no electrical load is connected, the first electric path can be completed, thus directing the power generated by the photovoltaic cell 403, such as through a port 406 of the photovoltaic cell, to the light source 401, such as through a second port 407 of the light source. In some cases, the first port 405 and the second port 407 of the light source can be the same port.

The second electric path 411 can be completed when at least one electrical load (e.g., electrical load 408) is connected to the photon battery assembly 400. In some instances, connecting an electrical load to the photon battery assembly can trigger the switch 409 to alternate from a default path (or from completing a different electrical path) to completing the second electric path 411. When an electrical load 408 is connected, the second electric path can be completed, thus directing the power generated by the photovoltaic cell 403, such as through the port 406, to the electrical load 408.

In some cases, the first electric path 410 and the second electric path 411 can be mutually exclusive. In some cases, a circuit can connect the port 406 of the photovoltaic cell 403, the second port 407 of the light source 401, and the electrical load 408 in series or in parallel and simultaneously, or discretely, direct at least some power to the light source and direct at least some power to the electrical load, such as when more power is being discharged by the photovoltaic cell than is being consumed by the electrical load.

In some cases, the circuitry can be controlled manually (e.g., manual connection of electrical load to photon battery assembly, such as pushing in a cable, nudges a switch component into a circuit position). Alternatively or in addition, the circuitry can be controlled by a controller (not shown in FIG. 4). The controller may be capable of sensing the connection(s) of one or more electrical loads with the photon battery assembly. The controller may be capable of completing different electrical circuit paths (e.g., first electric path 410, second electric path 411, etc.), such as via controlling one or more switch components (e.g., switch 409) or other electrical components.

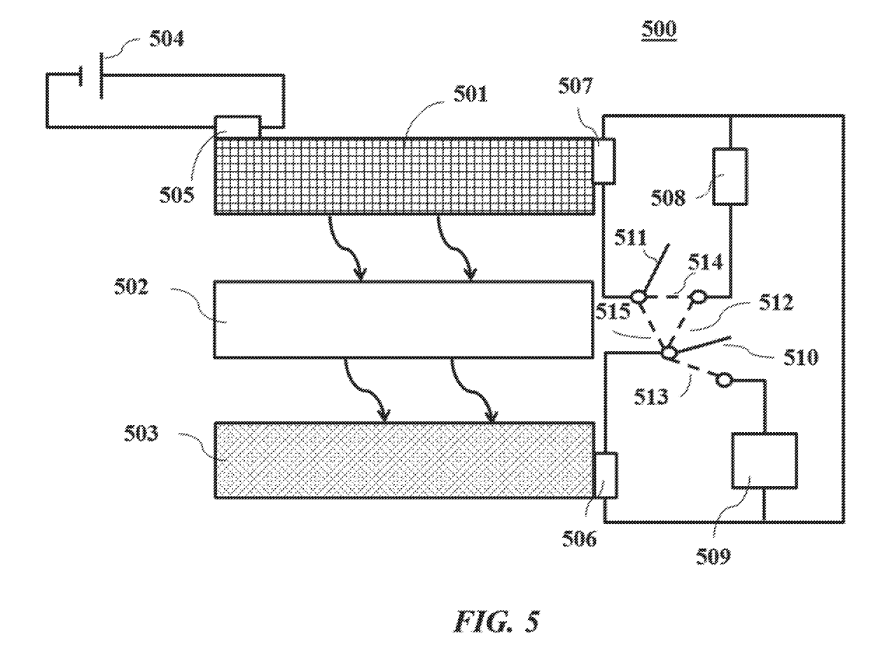

The controller can comprise one or more processors and non-transitory computer readable medium communicatively coupled to the one or more processors. The controller, via the one or more processors and machine readable instructions stored in memory, can be capable of regulating different charging and/or discharging mechanisms of the photon battery assembly 400. The controller may turn on an electrical connection between the light source 401 and the power supply 404 to start charging the photon battery assembly. The controller may turn off an electrical connection between the light source and the power supply to stop charging the photon battery assembly. The controller may turn on or off an electrical connection between the photovoltaic cell 403 and the electrical load 408. In some instances, the controller may be capable of detecting a charge level (or percentage) of the photon battery assembly. The controller may be capable of determining when the assembly is completely charged (or nearly completely charged) or discharged (or nearly completely discharged). For example, the photon battery assembly may further comprise a temperature sensor, heat sensor, optical sensor, or other type of sensor that is operatively coupled to the controller, wherein the sensors provide data indicative of charging level (or percentage). In some instances, the controller may be capable of maintaining a certain range of charge level (e.g., 5%˜95%, 10%˜90%, etc.) of the photon battery assembly, such as to maintain and/or increase the life of the photon battery assembly, which complete charge or complete discharge can detrimentally shorten. The controller may be capable of determining a power consumption rate of an electrical load and/or the light source. The controller may be configured to, based on such determination of power consumption rate, manipulate one or more circuitry in the photon battery assembly to direct power to the electrical load, the light source, both, and/or neither. FIG. 5 shows an exemplary photon battery assembly in communication with a rechargeable battery. Any and all circuits illustrated in FIG. 5 are not limited to such circuitry configurations. A photon battery assembly 500 can be charged by a power source 504 and discharge power to an electrical load 509. However, the electrical load 509 or other electrical loads that may draw power from the photon battery assembly may not necessarily be connected to the photon battery assembly at all times. In such cases, the power generated by the photovoltaic cell 503 can be wasted or lost from the energy storage system (e.g., photon battery assembly 500). When no electrical load is connected to the photon battery assembly, in some instances, the power generated by the photon battery assembly can be directed to charge a rechargeable battery 508. For example, at least some power generated by the photovoltaic cell can be directed to charge the rechargeable battery 508. The rechargeable battery 508 can be electrically coupled to the photon battery assembly 500 such that the rechargeable battery can, in some instances, supply power to a light source 501, and in some instances, be charged by a photovoltaic cell 503 of the photon battery assembly 500. The rechargeable battery can be a lithium ion battery.

In some instances, the photon battery assembly 500 in FIG. 5 and corresponding components thereof can parallel the photon battery assembly 300 in FIG. 3 and corresponding components thereof. In some instances, the photon battery assembly 500 in FIG. 5 and corresponding components thereof can parallel the photon battery assembly 400 in FIG. 4 and corresponding components thereof.

The photon battery assembly 500 can comprise a light source 501 powered primarily by a power source 504, such as through a first port 505 of the light source, a phosphorescent material 502 adjacent to a light-emitting surface of the light source, and a photovoltaic cell 503, which light-absorbing surface of the photovoltaic cell is adjacent to the phosphorescent material. The photovoltaic cell can discharge power to an electrical load 509 when the electrical load is in electrical communication with the photovoltaic cell. The photovoltaic cell can discharge power to a rechargeable battery 508 when the electrical load is not in electrical communication with the photovoltaic cell.

For example, a circuitry of the photon battery assembly 500 can comprise a switch 510 that either completes a first electric path 512 or a second electric path 513. In some cases, the switch can complete neither electric path (e.g., as shown in FIG. 5), and when neither electric path is completed, the power generated by the photon battery assembly can be wasted or lost from the energy storage system. The first electric path 512 can be completed when no electrical load (e.g., electrical load 509) is connected to the photon battery assembly 500. In some instances, completing the first electric path 512 can be the default state of the switch 510. When no electrical load is connected, the first electric path can be completed, thus directing the power generated by the photovoltaic cell 503, such as through a port 506 of the photovoltaic cell, to the rechargeable battery 508. The rechargeable battery can store the energy received from the photovoltaic cell. The rechargeable battery can discharge its own electrical power, such as to another electrical load, and/or back to the photon battery assembly 500, such as through a second port 507 of the light source 501. In some instances, the second port 507 and the first port 505 of the light source can be the same port.

The second electric path 513 can be completed when at least one electrical load (e.g., electrical load 509) is connected to the photon battery assembly 500. In some instances, connecting an electrical load to the photon battery assembly can trigger the switch 510 to alternate from a default path (or from completing a different electrical path) to completing the second electric path 513. When an electrical load 509 is connected, the second electric path can be completed, thus directing the power generated by the photovoltaic cell 503, such as through the port 506, to the electrical load 509.

In some cases, the first electric path 512 and the second electric path 513 can be mutually exclusive. In some cases, a circuit can connect the port 506 of the photovoltaic cell 503, the rechargeable battery 508, and the electrical load 509 in series or in parallel and simultaneously, or discretely, direct at least some power to the rechargeable battery and direct at least some power to the electrical load.

Alternatively or in addition, a circuitry of the photon battery assembly 500 can comprise a switch 511 that either completes a third electric path 514 or a fourth electric path 515. In some cases, the switch can complete neither electric path (e.g., as shown in FIG. 5), and when neither electric path is completed, the power generated by the photon battery assembly can be wasted or lost from the energy storage system. In some instances, completing the third electric path 514 can be the default state of the switch 511. When the third electric path is completed, power generated by the rechargeable battery 508 can be directed to the photon battery assembly 500, such as through the second port 507 of the light source 501. In some instances, the second port 507 and the first port 505 of the light source can be the same port. When the fourth electric path 515 is completed, the power generated by the photovoltaic cell 503, such as through the port 506, can be directed back to the photon battery assembly 500, such as through the second port 507 of the light source 501.

In some cases, the first electric path 512, the second electric path 513, the third electric path 514, and the fourth electric path 515 can be mutually exclusive. In some cases, a circuit can connect the port 506 of the photovoltaic cell 503, the rechargeable battery 508, the electrical load 509, the second port 507 of the light source 501, or any combination thereof in series or in parallel and simultaneously, or discretely, direct at least some power to or from different components.

In some cases, the circuitry can be controlled manually (e.g., manual connection of electrical load to photon battery assembly, such as pushing in a cable, nudges a switch component into a circuit position). Alternatively or in addition, the circuitry can be controlled by a controller (not shown in FIG. 5). The controller may be capable of sensing the connection(s) of one or more electrical loads with the photon battery assembly. The controller may be capable of sensing the connection(s) of one or more rechargeable batteries with the photon battery assembly and/or the one or more electrical loads. The controller may be capable of completing different electrical circuit paths (e.g., first electric path 512, second electric path 513, third electric path 514, fourth electric path 515, etc.), such as via controlling one or more switch components (e.g., switch 510, switch 511, etc.) or other electrical components.

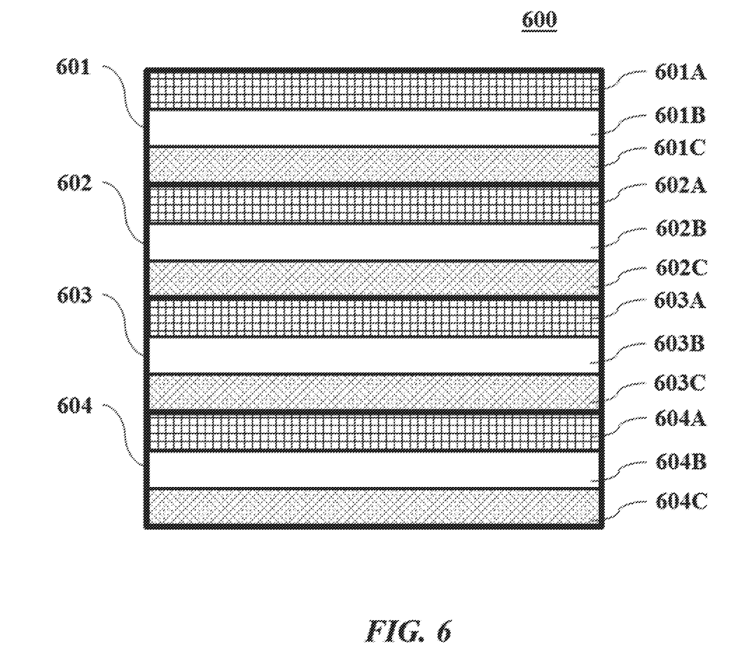

FIG. 6 shows a stack of a plurality of photon battery assemblies. A photon battery assembly can be connected to achieve different desired voltages, energy storage capacities, power densities, and/or other battery properties. For example, an energy storage system 600 comprises a stack of a first photon battery assembly 601, a second photon battery assembly 602, a third photon battery assembly 601, and a fourth photon battery assembly 601. The first photon battery assembly can comprise its own light source 601A, phosphorescent material 601B, and photovoltaic cell 601C. Similarly, the second photon battery assembly can comprise its own light source 602A, phosphorescent material 602B, and photovoltaic cell 602C. Similarly, the third photon battery assembly can comprise its own light source 603A, phosphorescent material 603B, and photovoltaic cell 603C. Similarly, the fourth photon battery assembly can comprise its own light source 604A, phosphorescent material 604B, and photovoltaic cell 604C. While FIG. 6 shows four photon battery assemblies stacked together, any number of photon battery assemblies can be stacked together. For example, at least 2, 3, 4, 5, 6, 7, 8, 9, 10, 15, 20, 25, 30, 35, 40, 45, 50, 100, 200, or more photon battery assemblies can be stacked together.

Each photon battery assembly can be configured as described in FIGS. 1-5. Alternatively, different components of the photon battery assembly (e.g., light source, phosphorescent material, photovoltaic cell) can be stacked in different configurations (e.g., orders) such that any phosphorescent material layer is adjacent to both a light source layer and a photovoltaic cell layer. For example, a first photovoltaic cell layer can be adjacent to a first phosphorescent material layer, which is also adjacent to a light source layer, which is also adjacent to a second phosphorescent material layer, which is also adjacent to a second photovoltaic cell layer. As in the example above, a phosphorescent material layer can act as intermediary layers between alternating layers of the photovoltaic cell and the light source. For example, a light source can have at least two light-emitting surfaces that are each in optical communication with distinct phosphorescent materials (e.g., different volumes of phosphorescent materials). For example, a photovoltaic cell can have at least two light-absorbing surfaces that are each in optical communication with distinct phosphorescent materials (e.g., different volumes of phosphorescent materials).

A plurality of photon battery assemblies can be electrically connected in series, in parallel, or a combination thereof. While FIG. 6 shows a vertical stack, the assemblies can be stacked in different configurations, such as in horizontal stacks on in concentric (or circular) stacks. In some instances, there may be interconnects and/or other electrical components between each photon battery assembly. In some instances, a controller can be electrically coupled to one or more photon battery assemblies (e.g., 601, 602, 603, 604, etc.) and be capable of managing the inflow and/or outflow of power from each or a combination of the battery assemblies.

As described elsewhere herein, photovoltaic cells in a photon battery assembly generate electrical power by absorbing optical energy from the phosphorescent material. However, if the phosphorescent material is too thick in depth, the optical energy emitted by the phosphorescent material may not be efficiently absorbed by the photovoltaic cell, due in part to other phosphorescent material obstructing optical paths to one or more light-absorbing surfaces of the photovoltaic cell. For example, the photons emitted by the outermost material (closest to the interface between the light absorbing surface of the photovoltaic cell and the phosphorescent material) of the phosphorescent material may be absorbed with less resistance than the photons emitted by the inner material (farthest from the interface between the phosphorescent material and the photovoltaic cell). Therefore, in some instances, it may be beneficial to have a relatively thin layer of phosphorescent material interfacing with a relatively large surface area of a light-absorbing surface of the photovoltaic cells. Provided herein are trench-like configurations of the photon battery assembly that can increase interfacial surface area between the phosphorescent material and the photovoltaic cells, thus allowing for more efficient absorption of optical energy by the photovoltaic cells.

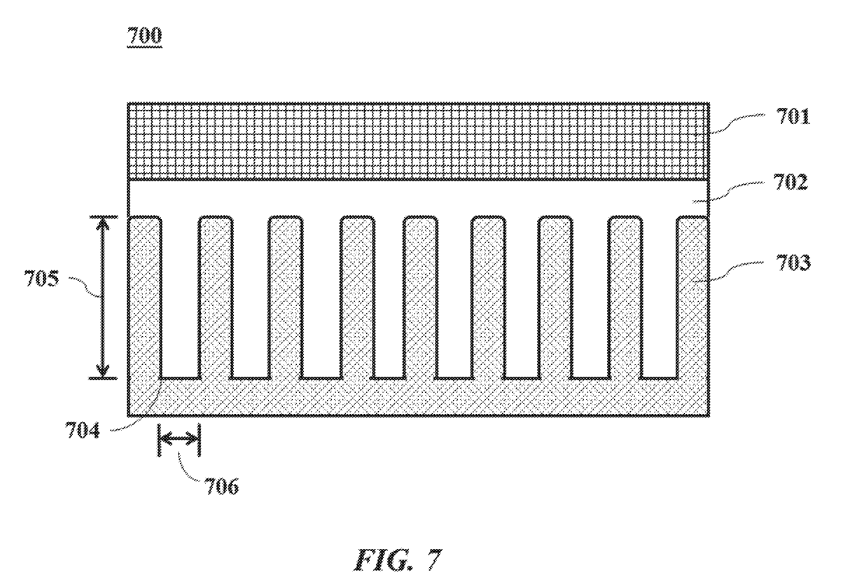

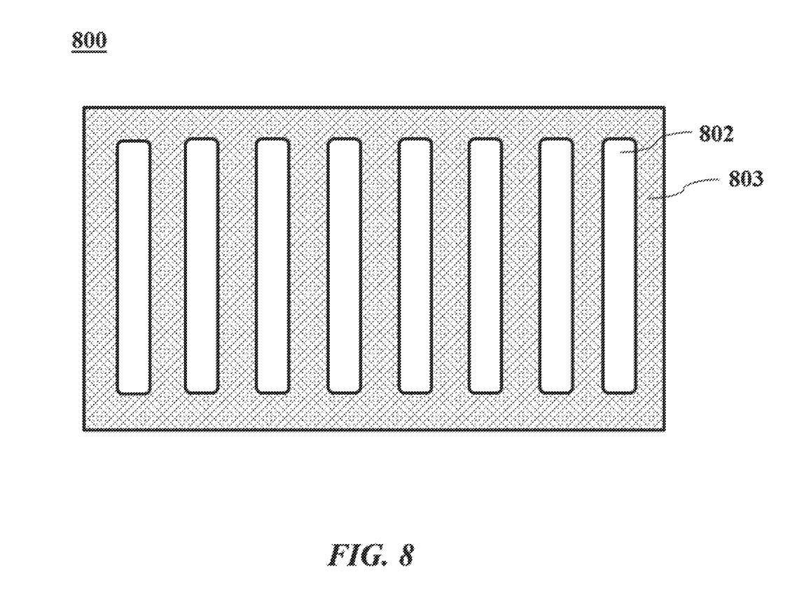

FIG. 7 shows a cross-sectional side view of an exemplary trench configuration of a photon battery assembly and FIG. 8 shows a cross-sectional top view of an exemplary trench configuration of a photon battery assembly. FIG. 7 and FIG. 8 may or may not be different views of the same trench configuration of a photon battery.

Referring to FIG. 7, a photon battery assembly 700 comprises a light source 701 (e.g., LEDs), phosphorescent material 702, and photovoltaic cells 703. As described elsewhere herein, a light-emitting surface of the light source can be adjacent to the phosphorescent material, and a light absorbing surface of the photovoltaic cells can be adjacent to the phosphorescent material.

In some instances, the photovoltaic cells 703 can comprise one or more depressions defined by corresponding protrusions. The depressions and/or the corresponding protrusions can be defined by the light-absorbing surface of the photovoltaic cells. For example, the photovoltaic cells can comprise one or more troughs and/or peaks. Alternatively or in addition, the photovoltaic cells can comprise grooves, cuts, trenches, wells, and/or other characterizations of depressions. A depression can be formed by etching, cutting, carving, digging, excavating, molding, pressurizing, and/or other mechanical methods. Alternatively or in addition, a depression can be formed by constructing, building, and/or assembling the photovoltaic cells to comprise the depression.

In some instances, a depth 705 of a depression 704 may be 100 times longer than a maximum width 705 (or diameter) of the depression 704. In some instances, a depth of a depression may be at least 2, 3, 4, 5, 6, 7, 8, 9, 10, 11, 12, 13, 14, 15, 20, 30, 40, 50, 60, 70, 80, 90, 100, 150, 200, 300, 400, 500, 600, 700, 800, 900, 1000 or more times longer than a maximum width of the depression. In some instances, a maximum width of a depression can be at least about 50 nanometers (nm), 60 nm, 70 nm, 80 nm, 90 nm, 100 nm, 110 nm, 120 nm, 130 nm, 140 nm, 150 nm, 200 nm, 300 nm, 400 nm, 500 nm, 600 nm, 700 nm, 800 nm, 900 nm, 1 millimeter (mm), 1.1 mm, 1.2 mm, 1.3 mm, 1.4 mm, 1.5 mm, 1.6 mm, 1.7 mm, 1.8 mm, 1.9 mm, 2.0 mm or greater. Alternatively, the maximum width of a depression can be less than about 50 nm. In some instances, a depth of a depression can be at least about 1 mm, 2 mm, 3 mm, 4 mm, 5 mm, 6 mm, 7 mm, 8 mm, 9 mm, 1 centimeter (cm), or greater. Alternatively, the depth of a depression can be less than about 1 mm. In some instances, a maximum width of a depression may be substantially the same as a maximum width of a protrusion. Alternatively, a maximum width of a depression may be at least 1%, 2%, 3%, 4%, 5%, 6%, 7%0, 8%, 9%, 10%, 200, 30%, 40⁰, 50%, 60%, 700, 80%, 90%, 100%, 200%, 300%, 400%, 500%, 1000%, 2000%, 3000%, 4000%, 5000%/o or more greater than a maximum width of a protrusion. Alternatively, the maximum width of a depression may less than the maximum width of a protrusion. In some instances, the photovoltaic cell 703 can comprise at least about 1, 2, 3, 4, 5, 6, 7, 8, 8, 10, 11, 12, 13, 14, 15, 20, 30, 40, 50, 60, 70, 80, 90, 100, 150, 200, 300, 400, 500, 600, 700, 800, 900, 1000, 2000, 3000, 4000, 5000, 6000, 7000, 8000, 9000, 10,000, 20,0000, or more depressions per centimeter length of the photovoltaic cell. Alternatively, the photovoltaic cell can comprise less than about 1 depression per centimeter length of the photovoltaic cell.

While FIG. 7 shows a certain number of depressions in the photovoltaic cell structure, the number of depressions in the photovoltaic cells is not restricted as such. The phosphorescent material 702 can interface with the significantly larger surface area of the light-absorbing surfaces of the photovoltaic cell 703 which define the depressions and/or corresponding protrusions, at least when compared to the surface area of planar light-absorbing surfaces of the photovoltaic cell (such as in FIG. 1).

In some embodiments, the photovoltaic cell 703 may be contacting the light source 701 (not shown in FIG. 7). For example, one or more light-emitting surfaces of the light source 701 can cap or cover the depressions (or wells) of the photovoltaic cell 703 by contacting the top (or peak) of the one or more protrusions defining the depressions. The light source can be in any configuration in which the phosphorescent material 702 is in optical communication with the light source. In some instances, if the phosphorescent material is capable of absorbing natural light, the light source may not be required in the assembly, and the photon battery assembly 700 can be in any configuration in which the phosphorescent material is in optical communication with a natural light source (e.g., sunlight).

As described elsewhere herein, phosphorescent material 702 in a photon battery assembly 700 store energy over a finite duration of time by absorbing optical energy at a first wavelength from a light source 701 and, after a time delay, emitting optical energy at a second wavelength, such as to photovoltaic cells 703. However, if the phosphorescent material is too thick in depth, the optical energy emitted by the light source may not be efficiently absorbed by the phosphorescent material, due in part to other phosphorescent material obstructing optical paths from one or more light-emitting surfaces of the light source. For example, the photons emitted by the light source may be absorbed with less resistance by the outermost material (closest to the interface between the light emitting surface of the light source and the phosphorescent material) of the phosphorescent material than by the inner material (farthest from the interface between the phosphorescent material and the light source). Therefore, in some instances, it may be beneficial to have a relatively thin layer of phosphorescent material interfacing with a relatively large surface area of a light-emitting surface of the light source.

In some embodiments (not shown in FIG. 7), the light source 701 may comprise one or more depressions defined by corresponding protrusions. The depressions and/or corresponding protrusions can be defined by light-emitting surfaces of the light source. For example, the light source can comprise one or more troughs and/or peaks. In some instances, a depth of a depression may be 100 times longer than a maximum width (or diameter) of the depression. The phosphorescent material 702 can interface with the significantly larger surface area of the light-emitting surfaces of the light source 701 which define the depressions and/or corresponding protrusions, at least when compared to the surface area of planar light-emitting surfaces of the light source (such as in FIG. 1 and FIG. 7), thus allowing for more efficient absorption of optical energy by the phosphorescent material.

In some embodiments (not shown in FIG. 7), both the light source 701 and the photovoltaic cells 703 may comprise one or more depressions defined by corresponding protrusions. In some instances, the depressions and/or corresponding protrusions defined by the light source can be complementary to the depressions and/or corresponding protrusions defined by the photovoltaic cells. For example, a protrusion of the light source may fit, with at least some room, within a depression of the photovoltaic cells, wherein the phosphorescent material lies within the at least some room between the light source and the photovoltaic cells. Alternatively or in addition, a protrusion of the photovoltaic cells may fit, with at least some room, within a depression of the light source, wherein the phosphorescent material lies within the at least some room between the light source and the photovoltaic cells. Beneficially, such configurations can increase the interfacial surface areas both between the phosphorescent material and the light source and between the phosphorescent material and the photovoltaic cells, thus allowing for more efficient absorption and emission of optical energy by the phosphorescent material as well as efficient absorption of optical energy by the photovoltaic cells.

Referring to FIG. 8, a cross-sectional top view of a trench configuration of a photon battery assembly is shown. A photon battery assembly 800 comprises a light source (not shown in FIG. 8), phosphorescent material 802, and photovoltaic cells 803. As described elsewhere herein, a light-emitting surface of the light source can be adjacent to the phosphorescent material, and a light absorbing surface of the photovoltaic cells can be adjacent to the phosphorescent material. The photovoltaic cell may comprise one or more depressions that go into the plane of FIG. 8 and one or more corresponding protrusions that come out of the plane of FIG. 8. In some cases, a depression may be elongated in at least one dimension (that is not the depth) and aligned in a horizontal or vertical array, such as is shown in FIG. 8. The depression may not be elongated. In some cases, depressions may be aligned in a grid having at least two axes (e.g., horizontal and vertical axes, x and y axes) that may or may not be at right angles to each other.

Alternatively or in addition, the phosphorescent material may interface with a light-absorbing surface of the photovoltaic cell that has any other shape, form, or structure, such as a planar structure (e.g., as in the photovoltaic cell 103 shown in FIG. 1). The other shape, form, or structure may increase interfacial surface area between the phosphorescent material and the photovoltaic cell than a planar structure within the same reference volume. Alternatively or in addition, the phosphorescent material may interface with a light-emitting surface of the light source that has any other shape, form, or structure, such as a planar structure (e.g., as in the light source 101 shown in FIG. 1). The other shape, form, or structure may increase interfacial surface area between the phosphorescent material and the light source than a planar structure within the same reference volume.

In some embodiments, alternative to or in addition to the optical energy, the phosphorescent material may absorb kinetic energy, and after a time delay, emit optical energy converted from the kinetic energy to be absorbed by the photovoltaic cell. For example, radioactive material can excite the phosphorescent material with high energy particles (having high kinetic energy).

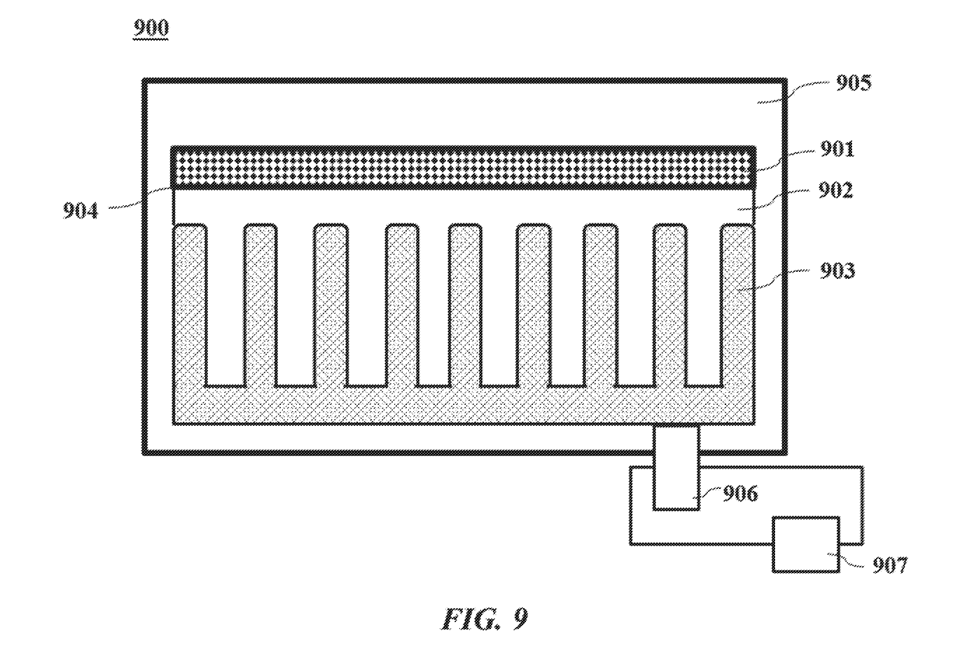

FIG. 9 shows a photon battery assembly comprising radioactive material. The photon battery assembly 900 can comprise radioactive material 901, phosphorescent material 902, and photovoltaic cells 903. In some instances, the radioactive material 901 can substitute the light source in previous embodiments of the photon battery assembly (e.g., light source in FIGS. 1-8). In some instances, the radioactive material 901 can be in addition to the light source in previous embodiments (light source not shown in FIG. 9).

As described elsewhere herein, the phosphorescent material 902 can be adjacent to a light-absorbing surface of the photovoltaic cell 903. In some instances, as described elsewhere herein (and as shown in FIG. 9), the phosphorescent material may interface with a light-absorbing surface of the photovoltaic cell 903 that defines one or more depressions and/or corresponding protrusions. In other instances, the phosphorescent material may interface with a light-absorbing surface of the photovoltaic cell that has any other shape, form, or structure, such as a planar structure (e.g., as in the photovoltaic cell 103 shown in FIG. 1). The phosphorescent material may further be adjacent to the radioactive material 901. For example, the phosphorescent material can be adjacent to a high energy particle emitting surface of the radioactive material. In some instances, the radioactive material may be shielded from the rest of the photon battery assembly (e.g., phosphorescent material, photovoltaic cell, etc.) in a shell, casing, membrane, or other compartment 904. The compartment 904 may allow high energy particles (or otherwise kinetic energy) to permeate or pass through the compartment to contact the phosphorescent material. In some instances, relatively heavy elements such as lead can be used to reflect radioactive emission (e.g., high energy particles) towards the phosphorescent material.

While FIG. 9 shows the radioactive material 901 positioned above both the phosphorescent material 902 and the photovoltaic cell 903, the configuration of the photon battery assembly 900 is not limited to such. For example, the radioactive material may be positioned in the middle, the bottom, and/or in a location between the trench-like configurations of the photovoltaic cell. In another example, the radioactive material may be positioned between at least a portion of the photovoltaic cell and the phosphorescent material. In another example, the radioactive material may be in one or more different compartments and placed in different locations relative to the photovoltaic cell and/or the phosphorescent material. The radioactive material may be positioned in a location where high energy particles emitted by the radioactive material is capable of reaching and/or travelling through the phosphorescent material.

The radioactive material 901 can emit high energy particles, such as as products of radioactive decay. Radioactive decay can include alpha decay, beta decay, gamma decay, and/or spontaneous fission. The high energy particles can be alpha particles (e.g., nucleons), beta decay products (e.g., electrons, positrons, neutrino, etc.), gamma rays, and/or a combination thereof. The high energy particles can have high kinetic energy. The high energy particles can travel through the phosphorescent material 902 upon emission from the radioactive material and excite the phosphorescent material (e.g., absorb the kinetic energy of the high energy particles). The phosphorescent material can subsequently, after a time delay, emit optical energy, such as at a visible wavelength (e.g., 400-700 nm). In some instances, the rate of absorption of kinetic energy by the phosphorescent material can be faster than the rate of emission of optical energy by the phosphorescent material. The phosphorescent material can emit optical energy at other wavelengths or ranges of wavelengths in the electromagnetic spectrum. As described elsewhere herein, the photovoltaic cell 903 can absorb such optical energy emitted by the phosphorescent material and generate electrical power. The electrical power generated by the photovoltaic cell can be discharged to an electrical load 907, such as through a port 906 of the photovoltaic cell. In some instances, the photon battery assembly 900 can comprise an outer casing, shell or compartment 905 to house the radioactive material 901, phosphorescent material 902, and the photovoltaic cells 903, such as to contain any radiation that can escape the energy storage system during normal use. The compartment 905 can be configured to contain any radiation emitted by the radioactive material 901 from escaping the compartment 905. For example, the port 906 of the photovoltaic cell may be the only connection from outside the compartment 905 to inside the compartment 905.

For example, the radioactive material 901 can be strontium-90. Other examples of radioactive material can include, but are not limited to, tritium, beryllium-10, carbon-14, fluorine-18, aluminium-26, chlorine-36, potassium-40, calcium-41, cobalt-60, technetium-99, technetium-99m, iodine-129, iodine-131, xenon-135, caesium-137, gadolinium-153, bismuth-209, polonium-210, radon-222, thorium-232, uranium-235, plutonium-238, plutonium-239, americium-241, and californium-252.

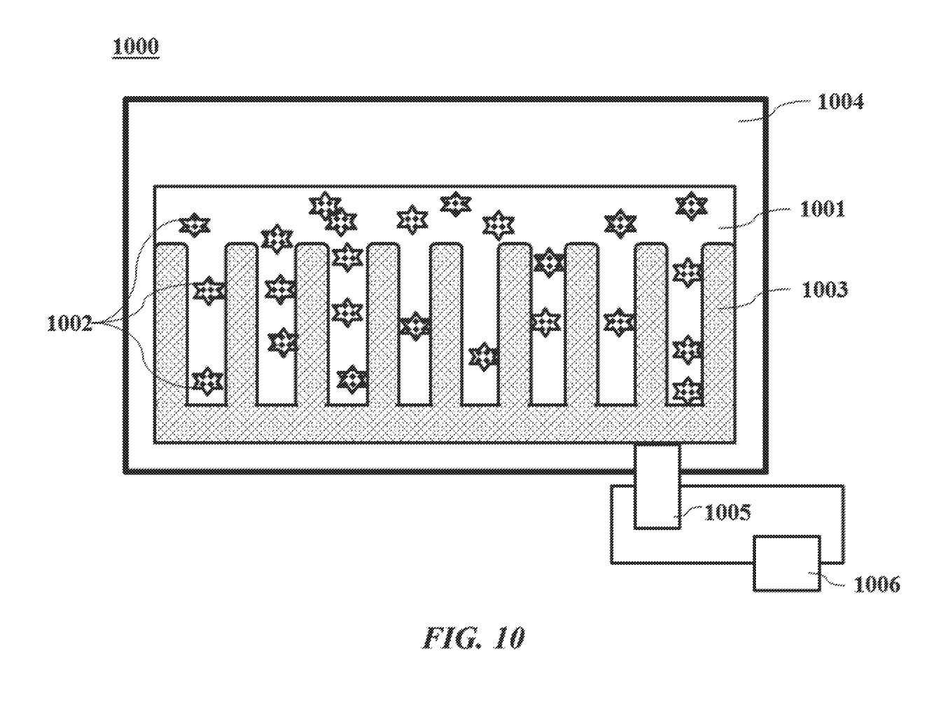

FIG. 10 shows a photon battery assembly comprising radioactive material in the phosphorescent material. In some instances, a photon battery assembly 1000 may comprise a phosphorescent material 1001 that comprises a radioactive material 1002. For example, instead of having a separate radioactive sample inserted into the photon battery assembly (such as in FIG. 9), the radioactive material can be integrated in the phosphorescent material. By way of example, a phosphorescent material comprising strontium aluminate doped with europium can be manufactured to have strontium-90 dispersed throughout the phosphorescent material.

The radioactive material 1002 can emit high energy particles from within the phosphorescent material 1001, such as products of radioactive decay. The high energy particles can travel through the phosphorescent material upon emission from the radioactive material and excite the phosphorescent material (e.g., absorb the kinetic energy of the high energy particles). The phosphorescent material can subsequently, after a time delay, emit optical energy. In some instances, the rate of absorption of kinetic energy by the phosphorescent material can be faster than the rate of emission of optical energy by the phosphorescent material. As described elsewhere herein, the photovoltaic cell 1003 can absorb such optical energy emitted by the phosphorescent material and generate electrical power. The electrical power generated by the photovoltaic cell can be discharged to an electrical load 1006, such as through a port 1005 of the photovoltaic cell. In some instances, the photon battery assembly 1000 can comprise an outer casing, shell or compartment 1004 to house the phosphorescent material 1001 comprising the radioactive material 1002 and the photovoltaic cells 1003, such as to contain any radiation that can escape the energy storage system during normal use. The compartment 1004 can be configured to contain any radiation emitted by the radioactive material 1002 from within the phosphorescent material 1001 from escaping the compartment 1004. For example, the port 1005 of the photovoltaic cell may be the only connection from outside the compartment 1004 to inside the compartment 1004.

In some instances, a photon battery assembly comprising radioactive material can provide higher energy storage capacity (e.g., energy density, power density, etc.) than a photon battery comprising a light source after a single charge of the same volume. In some instances, the energy storage capacity of a radioactive material comprising photon battery assembly can depend on a half-life of a radioactive material in the photon battery assembly. For example, a radioactive material can provide continuous kinetic energy to the photon battery assembly as it undergoes radioactive transformation. In some instances, a photon battery assembly comprising radioactive material can be disposed of after near full consumption of the radioactive material (e.g., emitting negligent kinetic energy). In some instances, radioactive material can be replaced after near full consumption. In some instances, the phosphorescent material and/or photovoltaic cells can be recycled (e.g., in other photon battery assemblies) after near full consumption of the radioactive material. In some instances, a photon battery assembly can comprise both radioactive material and a light source, and may be recharged via methods described elsewhere herein (e.g., providing electric power to the light source). For example, even after near full consumption of the radioactive material, the photon battery assembly may be used via recharging with electrical energy.

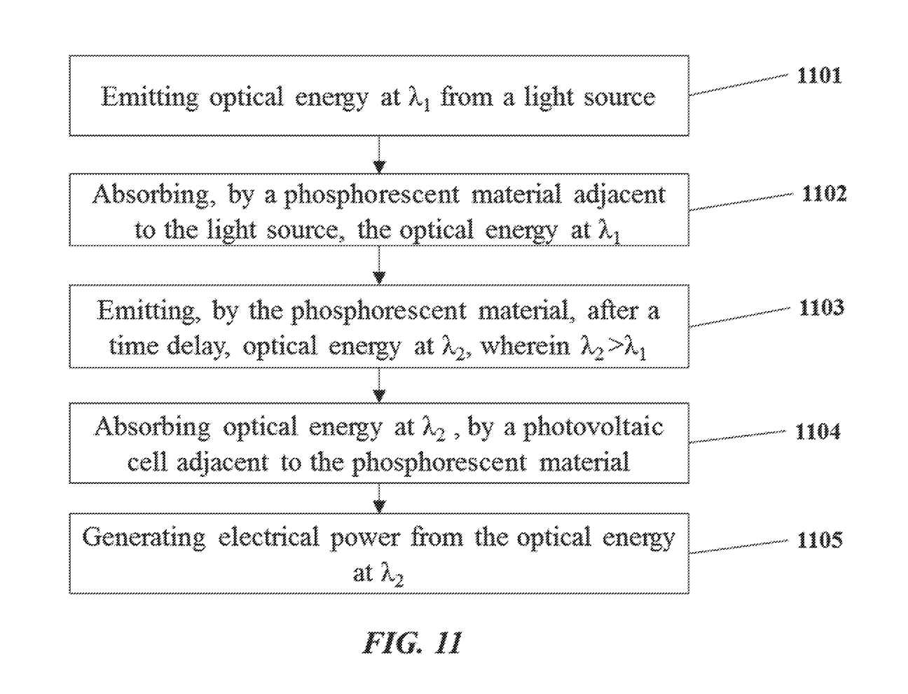

FIG. 11 illustrates a method of storing energy in a photon battery. The method can comprise, at a first step 1301, emitting optical energy at a first wavelength (e.g., λ₁) from a light source. The optical energy at the first wavelength can be emitted from a light-emitting surface of the light source. The light source can be an artificial light source, such as a LED, laser, or lamp. The light source can be a natural light source. The light source can be powered by an electric power source, such as another energy storage device (e.g., battery, supercapacitors, capacitors, fuel cells, etc.) or another power supply (e.g., electrical grid).

At a second step 1102, a phosphorescent material that is adjacent to the light source can absorb the optical energy at the first wavelength. For example, the phosphorescent material can be adjacent to the light-emitting surface of the light source. In some instances, the first wavelength can be an ultraviolet wavelength (e.g., 20-400 nm).

At a next step 1103, after a time delay, the phosphorescent material can emit optical energy at a second wavelength (e.g., λ₂). In some instances, the first wavelength can be a visible wavelength (e.g., 400-700 nm). The second wavelength can be greater than the first wavelength. That is, the optical energy at the first wavelength can be at a higher energy level than the optical energy at the second wavelength. In some instances, the rate of absorption of the optical energy at the first wavelength by the phosphorescent material can be faster than the rate of emission of the optical energy at the second wavelength by the phosphorescent material.

At a next step 1104, a photovoltaic cell adjacent to the phosphorescent material can absorb the optical energy at the second wavelength that is emitted by the phosphorescent material. For example, a light-absorbing surface of the photovoltaic cell can absorb the optical energy at the second wavelength. In some instances, the photovoltaic cell can be tailored to absorb the wavelength or range of wavelengths that is emitted by the phosphorescent material. In some instances, the light-absorbing surface of the photovoltaic cell can comprise one or more depressions defined by corresponding protrusions to allow for increased interfacial surface area between the phosphorescent material and the photovoltaic cell.

At a next step 1105, the photovoltaic cell can convert the absorbed optical energy at the second wavelength and generate electrical power. In some instances, the electrical power generated by the photovoltaic cell can be used to power an electrical load that is electrically coupled to the photovoltaic cell. The electrical load can be an electronic device, such as a mobile phone, tablet, or computer. The electrical load can be a vehicle, such as a car, boat, airplane, or train. The electrical load can be a power grid. In some instances, at least some of the electrical power generated by the photovoltaic cell can be used to power the light source, such as when no electrical load is connected to the photovoltaic cell. In some instances, at least some of the electrical power generated by the photovoltaic cell can be used to charge a rechargeable battery (e.g., lithium ion battery), such as when no electrical load is connected to the photovoltaic cell. The rechargeable battery can in turn be used to power the light source. Beneficially, a photon battery assembly used in this method can be at least in part self-sustaining and prevent loss of energy from the system (e.g., other than from inefficient conversion of energy).

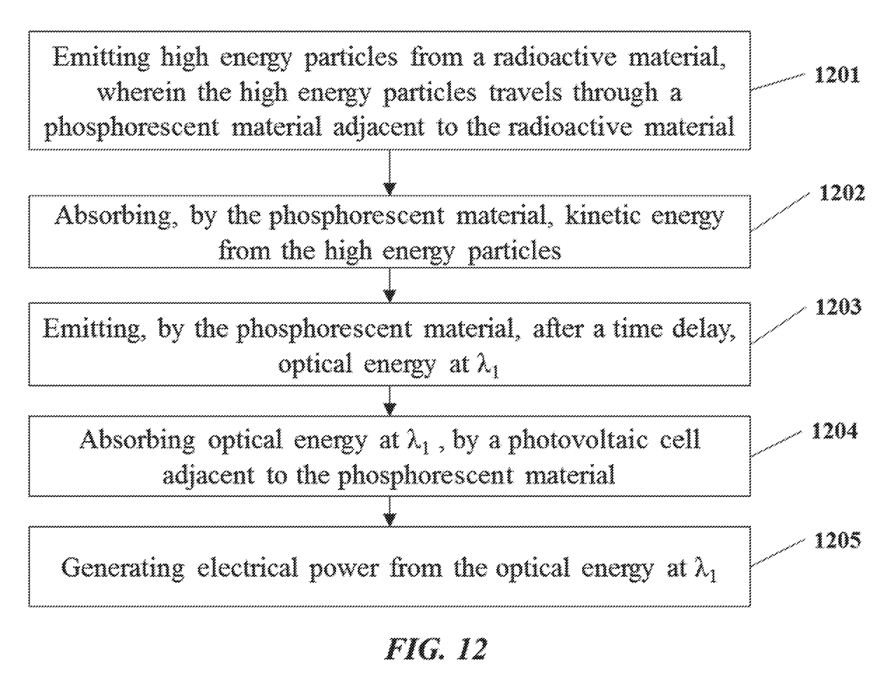

FIG. 12 illustrates a method of storing energy in a photon battery using radioactive material. The method can comprise, at a first step 1201, emitting high energy particles from a radioactive material. In some instances, the radioactive material can be adjacent to a phosphorescent material, in which case high energy particles are emitted into or reflected into the phosphorescent material. In some instances, the phosphorescent material can comprise the radioactive material, in which case high energy particles are emitted from within the phosphorescent material. In some instances, the radioactive material can substitute to the light source in some other embodiments discussed herein (e.g., such as in the method of FIG. 11). In some instances, the radioactive material can be in addition to the light source. The radioactive material can emit high energy particles, such as as products of radioactive decay. The high energy particles can have high kinetic energy. The high energy particles can travel through the phosphorescent material.

At a next step 1202, the phosphorescent material can absorb the kinetic energy from the high energy particles. For example, the phosphorescent material can be excited by the high energy particles. At a next step 1203, the phosphorescent material can, after a time delay, emit optical energy at a first wavelength (e.g., λ₁). In some instances, the first wavelength can be a visible wavelength (e.g., 400-700 nm). In some instances, the rate of absorption of the kinetic energy by the phosphorescent material can be faster than the rate of emission of the optical energy by the phosphorescent material.

At a next step 1204, a photovoltaic cell adjacent to the phosphorescent material can absorb the optical energy at the first wavelength that is emitted by the phosphorescent material. For example, a light-absorbing surface of the photovoltaic cell can absorb the optical energy at the first wavelength. In some instances, the photovoltaic cell can be tailored to absorb the wavelength or range of wavelengths that is emitted by the phosphorescent material. In some instances, the light-absorbing surface of the photovoltaic cell can comprise one or more depressions defined by corresponding protrusions to allow for increased interfacial surface area between the phosphorescent material and the photovoltaic cell.

At a next step 1205, the photovoltaic cell can convert the absorbed optical energy at the first wavelength and generate electrical power. In some instances, the electrical power generated by the photovoltaic cell can be used to power an electrical load that is electrically coupled to the photovoltaic cell. The electrical load can be an electronic device, such as a mobile phone, tablet, or computer. The electrical load can be a vehicle, such as a car, boat, airplane, or train. The electrical load can be a power grid. In some instances, at least some of the electrical power generated by the photovoltaic cell can be used to charge a rechargeable battery (e.g., lithium ion battery), such as when no electrical load is connected to the photovoltaic cell. Beneficially, the photon battery assembly used in this method can prevent loss of energy from the system (e.g., other than from inefficient conversion of energy).

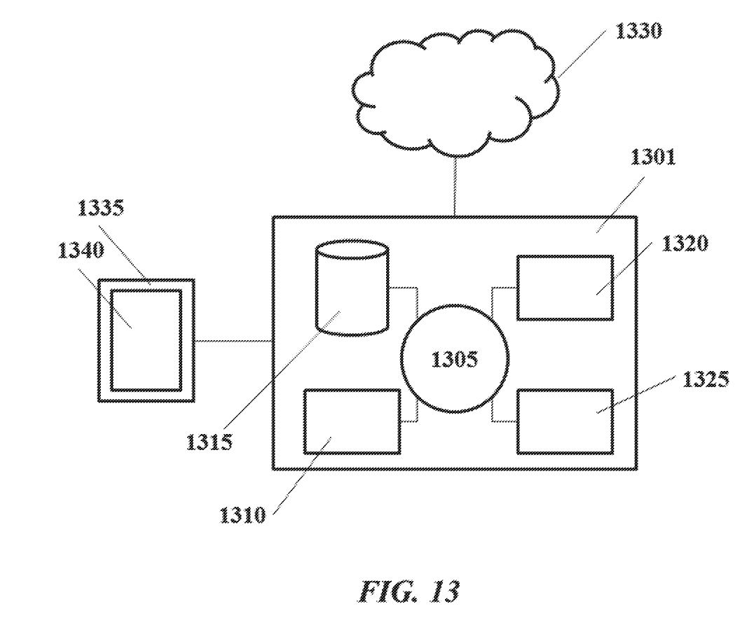

FIG. 13 shows a computer control system. The present disclosure provides computer control systems that are programmed to implement methods of the disclosure. A computer system 1301 is programmed or otherwise configured to regulate one or more circuitry in a photon battery assembly, in accordance with some embodiments discussed herein. For example, the computer system 1301 can be a controller, a microcontroller, or a microprocessor. In some cases, the computer system 1301 can be an electronic device of a user or a computer system that is remotely located with respect to the electronic device. The electronic device can be a mobile electronic device. The computer system 1301 can be capable of sensing the connection(s) of one or more electrical loads with a photon battery assembly, the connection(s) of one or more rechargeable batteries with a photon battery assembly, and/or the connection(s) of a photovoltaic cell and a light source within a photon battery assembly. The computer system 1301 may be capable of completing different electrical circuit paths (e.g., first electric path 410 in FIG. 4, etc.) or otherwise manipulating different circuitry within a photon battery assembly or involving a photon battery assembly, such as via controlling one or more switch components (e.g., switch 409 in FIG. 4, etc.) or other electrical components. The computer system 1301 may be capable of managing the inflow and/or outflow of power from each or a combination of photon battery assemblies electrically connected in series or in parallel, and in some cases, individually or collectively electrically communicating with a power source and/or an electrical load. The computer system 1301 may be capable of computing a rate of discharge of power from the photon battery and/or a rate of consumption of power by an electrical load. For example, the computer system may based on such computation, determine whether and how to direct power discharged from a photovoltaic cell to a light source, an external battery (e.g., lithium ion battery), and/or an electrical load. The computer system may be capable of adjusting or regulating a voltage or current of power input and/or power output of the photon battery. The computer system 1301 may be capable of adjusting and/or regulating different component settings. For example, the computer system may be capable of adjusting or regulating a brightness, intensity, color (e.g., wavelength, frequency, etc.), pulsation period, or other optical characteristics of a light emitted by a light source in the photon battery assembly. For example, the computer system may be configured to adjust a light emission setting from a light source depending on the type of phosphorescent material used in the photon battery.

For example, the computer system 1301 can be capable of regulating different charging and/or discharging mechanisms of a photon battery assembly. The computer system may turn on an electrical connection between a light source and a power supply to start charging the photon battery assembly. The computer system may turn off an electrical connection between the light source and the power supply to stop charging the photon battery assembly. The computer system may turn on or off an electrical connection between a photovoltaic cell and an electrical load. In some instances, the computer system may be capable of detecting a charge level (or percentage) of the photon battery assembly. The computer system may be capable of determining when the assembly is completely charged (or nearly completely charged) or discharged (or nearly completely discharged). In some instances, the computer system may be capable of maintaining a certain range of charge level (e.g., 5%-95%, 10%-90%, etc.) of the photon battery assembly, such as to maintain and/or increase the life of the photon battery assembly, which complete charge or complete discharge can detrimentally shorten.

The computer system 1301 includes a central processing unit (CPU, also “processor” and “computer processor” herein) 1305, which can be a single core or multi core processor, or a plurality of processors for parallel processing. The computer system 1301 also includes memory or memory location 1310 (e.g., random-access memory, read-only memory, flash memory), electronic storage unit 1315 (e.g., hard disk), communication interface 1320 (e.g., network adapter) for communicating with one or more other systems, and peripheral devices 1325, such as cache, other memory, data storage and/or electronic display adapters. The memory 1310, storage unit 1315, interface 1320 and peripheral devices 1325 are in communication with the CPU 1305 through a communication bus (solid lines), such as a motherboard. The storage unit 1315 can be a data storage unit (or data repository) for storing data. The computer system 1301 can be operatively coupled to a computer network (“network”) 1330 with the aid of the communication interface 1320. The network 1330 can be the Internet, an internet and/or extranet, or an intranet and/or extranet that is in communication with the Internet. The network 1330 in some cases is a telecommunication and/or data network. The network 1330 can include one or more computer servers, which can enable distributed computing, such as cloud computing. The network 1330, in some cases with the aid of the computer system 1301, can implement a peer-to-peer network, which may enable devices coupled to the computer system 1301 to behave as a client or a server.

The CPU 1305 can execute a sequence of machine-readable instructions, which can be embodied in a program or software. The instructions may be stored in a memory location, such as the memory 1310. The instructions can be directed to the CPU 1305, which can subsequently program or otherwise configure the CPU 1305 to implement methods of the present disclosure. Examples of operations performed by the CPU 1305 can include fetch, decode, execute, and writeback.

The CPU 1305 can be part of a circuit, such as an integrated circuit. One or more other components of the system 1301 can be included in the circuit. In some cases, the circuit is an application specific integrated circuit (ASIC).

The storage unit 1315 can store files, such as drivers, libraries and saved programs. The storage unit 1315 can store user data, e.g., user preferences and user programs. The computer system 1301 in some cases can include one or more additional data storage units that are external to the computer system 1301, such as located on a remote server that is in communication with the computer system 1301 through an intranet or the Internet.

The computer system 1301 can communicate with one or more local and/or remote computer systems through the network 1330. For example, the computer system 1301 can communicate with all local energy storage systems in the network 1330. In another example, the computer system 1301 can communicate with all energy storage systems within a single assembly, within a single housing, and/or within a single stack of assemblies. In other examples, the computer system 1301 can communicate with a remote computer system of a user. Examples of remote computer systems include personal computers (e.g., portable PC), slate or tablet PC's (e.g., Apple® iPad, Samsung® Galaxy Tab), telephones, Smart phones (e.g., Apple® iPhone, Android-enabled device, Blackberry®), or personal digital assistants. The user can access the computer system 1301 via the network 1330.

Methods as described herein can be implemented by way of machine (e.g., computer processor) executable code stored on an electronic storage location of the computer system 1301, such as, for example, on the memory 1310 or electronic storage unit 1315. The machine executable or machine readable code can be provided in the form of software. During use, the code can be executed by the processor 1305. In some cases, the code can be retrieved from the storage unit 1315 and stored on the memory 1310 for ready access by the processor 1305. In some situations, the electronic storage unit 1315 can be precluded, and machine-executable instructions are stored on memory 1310.

The code can be pre-compiled and configured for use with a machine having a processor adapted to execute the code, or can be compiled during runtime. The code can be supplied in a programming language that can be selected to enable the code to execute in a pre-compiled or as-compiled fashion.

Aspects of the systems and methods provided herein, such as the computer system 1301, can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

The computer system 1301 can include or be in communication with an electronic display 1335 that comprises a user interface (UI) 1340 for providing, for example, user control options (e.g., start or terminate charging, start or stop powering an electrical load, route power back to self-charging, etc.). Examples of UI's include, without limitation, a graphical user interface (GUI) and web-based user interface.

Methods and systems of the present disclosure can be implemented by way of one or more algorithms. An algorithm can be implemented by way of software upon execution by the central processing unit 1305. The algorithm can, for example, change circuitry of a photon battery assembly or a stack of photon battery assemblies based on, for example, sensing the connection(s) of one or more electrical loads with a photon battery assembly, the connection(s) of one or more rechargeable batteries with a photon battery assembly, and/or the connection(s) of a photovoltaic cell and a light source within a photon battery assembly. The algorithm may be capable of completing different electrical circuit paths (e.g., first electric path 410 in FIG. 4, etc.) within a photon battery assembly or involving a photon battery assembly, such as via controlling or directing one or more switch components (e.g., switch 409 in FIG. 4, etc.) or other electrical components. The algorithm may be capable of managing the inflow and/or outflow of power from each or a combination of photon battery assemblies electrically connected in series or in parallel, and in some cases, individually or collectively electrically communicating with a power source and/or an electrical load.

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

1. A system for storing energy, comprising:
a light source configured to emit optical energy at a first wavelength from a surface of said light source;
a phosphorescent material adjacent to said surface of said light source, wherein said phosphorescent material is configured to (i) absorb said optical energy at said first wavelength, and (ii) at a rate slower than a rate of absorption, emit optical energy at a second wavelength, wherein said second wavelength is greater than said first wavelength; and
a photovoltaic cell adjacent to said phosphorescent material, wherein said photovoltaic cell is configured to (i) absorb optical energy at said second wavelength through a surface of said photovoltaic cell, and (ii) generate electrical power from optical energy.

2. The system of claim 1, wherein said light source is a light-emitting diode (LED).

3. The system of claim 1, wherein said photovoltaic cell is electrically coupled to an electrical load and at least part of said electrical power generated by said photovoltaic cell powers said electrical load.

4. The system of claim 1, wherein said photovoltaic cell is electrically coupled to said light source and at least part of said electrical power generated by said photovoltaic cell powers said light source.

5. The system of claim 1, wherein a rechargeable battery is electrically coupled to said light source and said photovoltaic cell, and wherein at least part of said electrical power generated by said photovoltaic cell charges said rechargeable battery, and wherein at least part of electrical power discharged by said rechargeable battery powers said light source.

6. The system of claim 1, wherein said phosphorescent material comprises strontium aluminate and europium.

7. The system of claim 1, further comprising a radioactive material that emits high energy particles, wherein said high energy particles are capable of travelling through said phosphorescent material, wherein said phosphorescent material is configured to (i) absorb kinetic energy from said high energy particles, and (ii) at a rate slower than the rate of absorption of kinetic energy, emit optical energy at said second wavelength.

8. The system of claim 7, wherein said phosphorescent material comprises said radioactive material.

9. The system of claim 1, wherein said photovoltaic cell comprises a plurality of depressions between protrusions and wherein said surface of said photovoltaic cell is a surface of a protrusion defining a depression.

10. A method for storing energy, comprising:
(a) emitting optical energy at a first wavelength from a surface of a light source;
(b) absorbing, by a phosphorescent material adjacent to said surface of said light source, said optical energy at said first wavelength;
(c) at a rate slower than a rate of absorption, emitting, by said phosphorescent material, optical energy at a second wavelength, wherein said second wavelength is greater than said first wavelength;
(d) absorbing said optical energy at said second wavelength through a surface of a photovoltaic cell, wherein said surface of said photovoltaic cell is adjacent to said phosphor; and
(e) generating electrical power from said optical energy at said second wavelength.

11. The method of claim 10, wherein said light source is a light-emitting diode (LED).

12. The method of claim 10, further comprising powering an electrical load electrically coupled to said photovoltaic cell using said electrical power.

13. The method of claim 10, further comprising powering said light source using at least part of said electrical power, wherein said light source is electrically coupled to said photovoltaic cell.

14. The method of claim 10, further comprising (i) charging a rechargeable battery using at least part of said electrical power, wherein said rechargeable battery is electrically coupled to said photovoltaic cell and (ii) powering said light source using at least part of electrical power discharged by said rechargeable battery, wherein said rechargeable battery is electrically coupled to said light source.

15. The method of claim 10, wherein said photovoltaic cell comprises a plurality of depressions between protrusions and wherein said surface of said photovoltaic cell is a surface of a protrusion defining a depression.

16.-20. (canceled)
